(19) United States
(12) Patent Application Publication
(10) Pub. No.: US 2006/0205096 A1
(43) Pub. Date: Sep. 14, 2006

(54) Method for manufacturing nonlinear optical element

(75) Inventor: Yutaka Okabe, Tokyo (JP)

Correspondence Address: VENABLE LLP, P.O. BOX 34385, WASHINGTON, DC, 20045-9998, US

(73) Assignee: Oki Electric Industry Industry Co., Ltd., Tokyo (JP)

(21) Appl. No.: 11/364,006

(22) Filed: Mar. 1, 2006

(30) Foreign Application Priority Data
Mar. 9, 2005 (JP) 2005-065863

(51) Int. Cl. H01L 21/00

(52) U.S. Cl. 438/3; 438/466; 438/24

(57) ABSTRACT

An insulating film is formed on a first principal surface of the substrate. A periodic structure formation zone corresponding to a periodic structure formation region to be formed in the substrate, a plurality of polarization inversion zones corresponding to polarization inversion regions to be formed in a periodic arrangement in the periodic structure formation region, and a connection zone corresponding to a connection region to connect the plurality of polarization inversion regions, are set on the insulating film. The portions of the insulating film in the polarization inversion zones and the connection zone are removed, forming an insulating film pattern which exposes portions of the first principal surface of the substrate. A high voltage is applied, through an electrolytic solution, across the portions of the first principal surface exposed out of the insulating film pattern and the second principal surface of the substrate, to cause inversion of the polarization direction in the polarization inversion regions.

### BACKGROUND OF THE INVENTION

1. Field of the Invention

This invention relates to a method for manufacturing a nonlinear optical element, and in particular a nonlinear optical element having provided therein a periodic polarization inversion structure.

2. Description of the Related Art

When the optical amplitude of light input to an optical element is small, there is an approximately linear relation between the amplitude of the input light and the amplitude of the output light. In this case, when the amplitude of the input light is increased or decreased, the amplitude of the output light increases or decreases in proportion to the magnitude of the input light amplitude.

When on the other hand the optical amplitude of light input to an optical element becomes large, there is deviation from linearity, and so-called nonlinearity appears. “Nonlinear optical effect” is a general term for optical phenomena which occur as a result of such nonlinear properties. Optical elements which utilize nonlinear optical effects are called nonlinear optical elements. Such nonlinear optical elements enable the realization of optical control functions, such as optical frequency conversion, parametric optical amplification, and optical switch with optical controlling. These functions are not possible attained by using linear optical elements making use of linear relation between the amplitude of output light and the amplitude of input light.

QPM-type nonlinear optical elements (hereafter called “QPM elements”) have been developed heretofore, as nonlinear optical elements. The QPM elements realize quasi-phase matching (QPM) to perform wavelength conversion by means of an optical waveguide in which a periodic polarization inversion structure is formed.

One method for forming a polarization inversion structure in a QPM element involved periodically providing electrodes, of metal or a similar material, on a first principal surface of a substrate, and applying a voltage across these electrodes and an electrode provided on a second principal surface to cause periodic polarization inversion in the substrate. Another method involved periodically providing an insulating film on a first principal surface of a substrate, and applying a voltage to the substrate in an electrolytic solution through the electrolytic solution, to cause periodic polarization inversion in the substrate (see for example Japanese Patent Laid-open No. 2002-31827, and “Electrode geometries for periodic poling of ferroelectric materials”, M. Reich et al, Optics Letters, Vol. 23 No. 23, Dec. 1, 1998).

The method of providing metal or other electrodes on a substrate and causing polarization inversion must be performed with the voltage applied in vacuum or in insulating oil. When polarization inversion is induced in vacuum, the manufactured device must be large in size. Also, because the resistance value depends on the thickness of the electrode provided on the substrate, the supply of charge to the substrate becomes uneven. Due to the unevenness of the supply of charge, the polarization inversion regions become uneven, that is, polarization inversion may not occur in regions where inversion is desired. As a result, there are technical problems to be overcome that the conditions for controlling the thickness of the electrode become stringent.

On the other hand, in methods involving application of a voltage through an electrolytic solution, an insulating film having periodic opening is provided on the surface of a nonlinear optical material, and a voltage is applied to the substrate through the electrolytic solution.

Referring to FIGS. 7A and 7B, an insulating film provided on the surface of a nonlinear optical material in the prior art will be explained. FIGS. 7A and 7B are schematic diagrams for explaining a conventional method of manufacture of a nonlinear optical element, respectively. Specifically, FIG. 7A is a plane view seen from the upper face, and FIG. 7B shows a sectional view taken along the line C-C in FIG. 7A.

First, an insulating film (omitted from the drawings) is formed on the first principal surface 12 of the substrate 10 made of a nonlinear optical material. The insulating film has set thereto polarization inversion zones which correspond to polarization inversion regions to be formed in a periodic arrangement on the substrate. Next, the portions of the insulating film in the polarization inversion zones 54 are removed to provide openings 27, thereby forming an insulating film patter 24.

Thereafter, by applying a voltage in an electrolytic solution between exposed portions of the first principal surface 12 and the second principal surface 14 via the electrolytic solution, the polarization is inverted in the designated polarization inversion zones 54 of the substrate 10.

However, it is known that when a voltage is applied through an electrolytic solution as explained above, the polarization-inverted portions do no extend to the entire preset polarization inversion regions, and accordingly there remain regions in which only partial polarization inversion occurs. Regions in which polarization inversion does not occur are assumed to include, cases in which an entire single polarization inversion region does no undergo polarization inversion among the plurality of periodically formed polarization inversion regions, and cases in which polarization inversion occurs in a portion of a single polarization inversion region, but polarization inversion does not occur in the other portion.

It is thought that a source of polarization inversion is not readily induced when the area of the opening is small. Further, although a source of polarization inversion can be readily induced in the corner portions of an opening, the rectangular shape of the opening may also be a reason for the difficulty in spreading to the entire opening.

This invention was devised in light of the above-described problems.

Accordingly, an object of this invention is to provide a method of manufacture of a nonlinear optical element in which polarization inversion occurs uniformly over the entirety of a polarization inversion region of the substrate.

### SUMMARY OF THE INVENTION

In order to achieve the above object, according to a first aspect of the invention, there is provided a method of manufacture of a nonlinear optical element having a periodic polarization inversion structure. The method comprises the following processes.

First, a substrate made of nonlinear optical material is prepared. Then, an insulating film is formed on a first principal surface of the substrate. Then, periodic structure formation zones, peripheral zones, polarization inversion zones, and connection zones are set on the insulating film. The periodic structure formation zones correspond to periodic structure formation regions to be formed in the substrate. The peripheral zones are adjacent to periodic structure formation zones. The polarization inversion zones correspond to a plurality of polarization inversion regions which are to be placed periodically and formed in periodic structure formation regions. The connection zones are in peripheral zones and correspond to connection regions to be formed in the substrate which connect the plurality of polarization inversion regions to be formed in the substrate. After setting these zones, the polarization inversion zone and connection zone portions of the insulating film are removed, and the first principal surface of the substrate is exposed in these portions, and as a result an insulating film pattern is formed. Next, a high voltage is applied, through an electrolytic solution, across the portions of the first principal surface exposed out of the insulating film pattern and a second principal surface, to cause inversion of the polarization direction in the substrate portions of the polarization inversion regions.

According to a method of manufacture of a nonlinear optical element of the first aspect of this invention, the plurality of polarization inversion regions arranged periodically are connected by the connection regions. Consequently the source causing the polarization inversion which occurs in one polarization inversion region or a connection region tend to spread into other polarization inversion regions. Hence the entirety of polarization inversion regions exposed out of the insulating film pattern on the substrate undergoes uniform polarization inversion.

When implementing the above-described method of manufacture of a nonlinear optical element, it is preferable that, in the process of forming an insulating film pattern, the polarization inversion zones and connection zones be set as follows. Polarization inversion zones are set in a rectangular shape, with the length direction in a first direction, and the width of which is the first width. Connection zones are set in a rectangular shape, with the length direction in a second direction perpendicular to the first direction, and with the width as a second width greater than the first width.

By setting polarization inversion zones as rectangular shapes with length direction in the first direction and with width set as the first width, and by setting connection zones as rectangular shapes with length direction in a second direction perpendicular to the first direction and with width set as a second width greater than the first width, the width of connection zones corresponding to connection regions is greater than the width of polarization inversion zones corresponding to polarization inversion regions. As a result, the source giving rise to polarization inversion occurs more readily in connection regions.

According to a second aspect of the invention, in the process of formation of an insulating film pattern, it is preferable that the polarization inversion zones and connection zones be set as follows. Polarization inversion zones are set in rectangular shapes, the length direction of which is a first direction, and the width of which is a first width. Peripheral zones are set separately along both sides of the periodic structure formation zones in the direction of arrangement of polarization inversion zones; and connection zones are set in rectangular shapes in each of the preset peripheral zones, with the length direction in a second direction perpendicular to the first direction, and with width set to a second width greater than the first width.

When the separate connection zones are set separately on either side along the polarization inversion zones in the arrangement direction, the source causing polarization inversion, which occurs in connection regions, spreads from both sides of the polarization inversion regions, so that polarization inversion can be easily induced in the entirety of separate polarization inversion regions.

### BRIEF DESCRIPTION OF THE DRAWINGS

The foregoing and other objects, features and advantages of the present invention will be better understood from the following description taken in connection with the accompanying drawings, in which:

FIGS. 1A and 1B are schematic diagrams for explaining the nonlinear optical element of a first embodiment, in which FIG. 1A is a plane view seen from above, and FIG. 1B shows a sectional view taken along the line A-A in FIG. 1A;

FIGS. 2A, 2B, 2C, and 2D are schematic diagrams for explaining a method of manufacturing the nonlinear optical element of the first embodiment, in which FIGS. 2A and 2C are plane views seen from above, FIG. 2B shows a sectional view taken along the line B-B in FIG. 2A, and FIG. 2D shows a sectional view taken along the line C-C in FIG. 2C; FIG. 3 is a schematic diagram for explaining a method of manufacture of a nonlinear optical element of the first embodiment;

FIGS. 4A and 4B are schematic drawings for explaining spreading of the source inducing polarization inversion of the first embodiment, in which FIG. 4A shows a case in which an insulating film pattern used in a conventional method is used, and FIG. 4B shows a case in which an insulating film pattern used in the method of the first embodiment is used;

FIGS. 5A and 5B are schematic drawings for explaining a method of manufacture of a nonlinear optical element of a second embodiment, in which FIG. 5A is a plane view seen from above, and FIG. 5B shows a sectional view taken along the line D-D in FIG. 5A; FIG. 6 is a schematic drawing for explaining the spreading of the source inducing polarization inversion of the second embodiment; and

FIGS. 7A and 7B are schematic drawings for explaining a conventional method of manufacture of a nonlinear optical element, in which FIG. 7A is a plane view seen from above, and FIG. 7B shows a sectional view taken along the line C-C in FIG. 7A.

### DESCRIPTION OF THE PREFERRED EMBODIMENTS

The present invention will be described hereinbelow with reference to the drawings showing respective embodiments. Incidentally, the drawings to be referred illustrate merely schematic constitutions and arrangements of the respective constituent elements on such a level that the inventions can be understood. Further, although suitable embodiments of the present invention will be described hereinbelow, the present invention is not limited to or by the illustrated embodiments.

First Embodiment

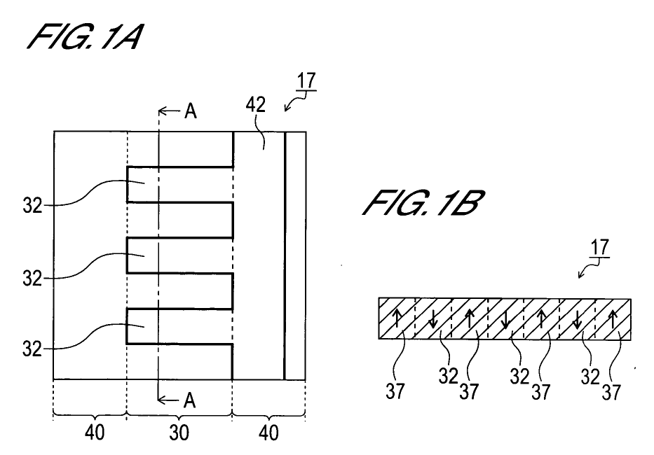

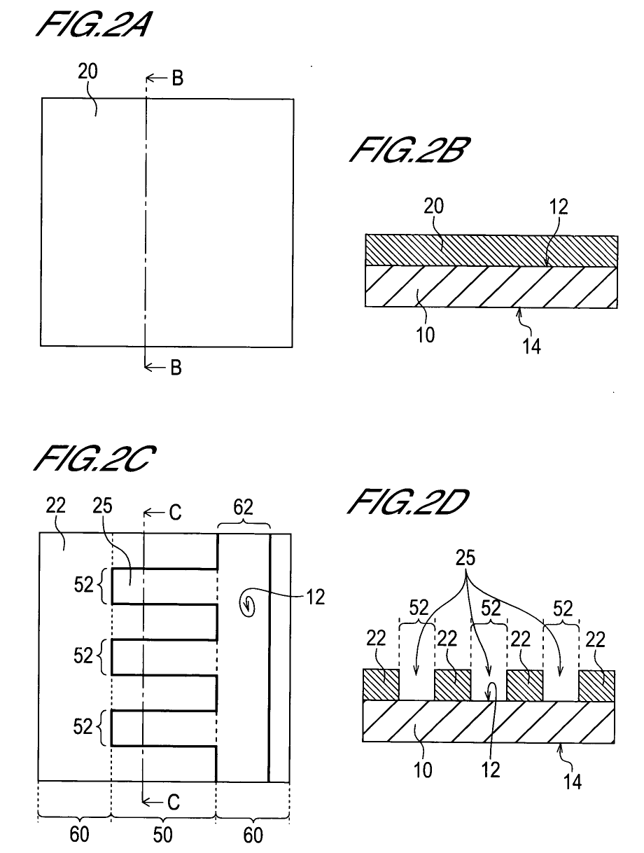

The nonlinear optical element formed in the method of manufacture of the first embodiment described below will be explained referring to FIGS. 1A and 1B.

The nonlinear optical element 17 has formed in the surface region on the side of the first principal surface of the substrate a periodic structure formation region 30, and a peripheral region 30 adjacent to the periodic structure formation region 30 on either side. The peripheral region 40 is a region other than the periodic structure formation region 30. The periodic structure formation region 30 has a long strip shape, that is, a stripe shape, within which a plurality of polarization inversion regions 32 are formed with constant width and in a periodic arrangement. In the polarization inversion regions 32, the polarization direction is inversed. Between polarization inversion regions 32 are formed polarization non-inversed regions 37 and the polarization direction is not inversed in polarization non-inversed regions 37. The peripheral region 40 comprises a connection region 42 which connects this plurality of polarization inversion regions 32. When a waveguide is formed within the periodic structure formation region 30 along the direction of arrangement of the polarization inversion regions 32, quasi-phase matching (QPM) is realized within the waveguide, and optical frequency conversion and other nonlinear optical effects occur. In the connection region 42 formed in the peripheral region 40, the polarization direction is inversed, but this inversion exerts no influence on operation of the nonlinear optical element 17.

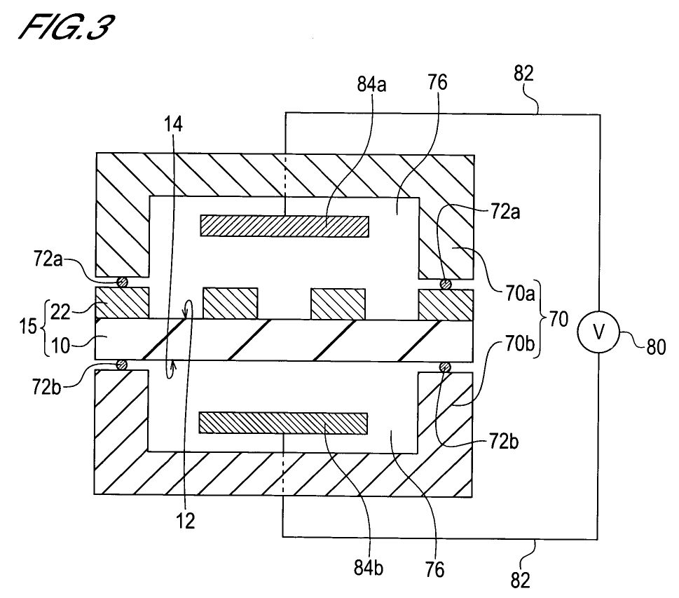

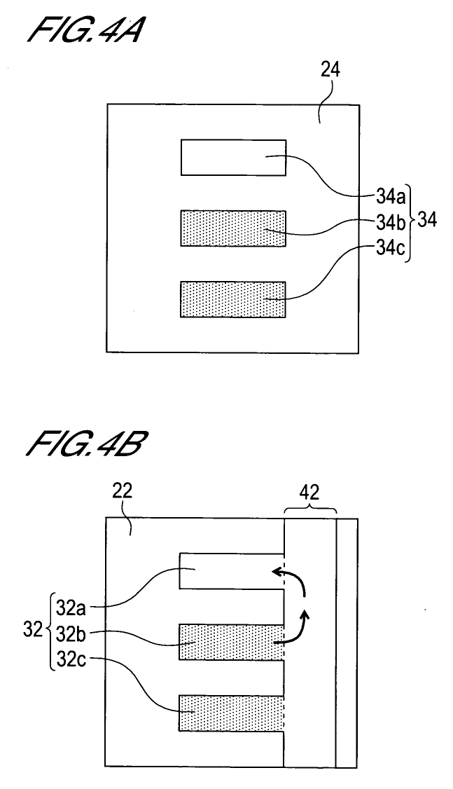

A method of manufacture of a nonlinear optical element with the above structure will be explained below with reference to FIGS. 2A, 2B, 2C, 2D, and 3.

First, a parallel-plane shape substrate 10 made of a nonlinear optical material is prepared. Nonlinear optical materials which can be used in this invention include ferroelectric crystals and ferroelectric crystals containing magnesium (Mg), iron (Fe), zinc (Zn), and oxide of these metals as impurities, as well as organic nonlinear optical materials. Examples of ferroelectric crystals include LiNbO₃ (LN), LiTaO₃ (LT), KTiOPO₄ (KTP), LiNbP₄P₁₂ (LNP), KNbO₃ (KN), Ba₂NaNb₅O₁₅ (BNP), KTiOAsO₄ (KTA), BaB₂O₄ (BBO), LiB₃O₇ (LBO), and KH₂PO₄ (KDP). Examples of organic nonlinear optical materials include metro-nitroaniline, 2-methyl-4-nitroaniline, 4-bromo-4-methoxychalcone, and dicyano-vinylanisole.

The insulating film 20 is formed on the first principal surface 12 of the substrate 10. The insulating film 20 is formed by, for example, applying a phenolic novolac resin or other photosensitive polymer film (hereafter called a “resist”) (FIGS. 2A and 2B).

This insulating film 20 is patterned to form the insulating film pattern 22. To this end, zones are set on the insulating film 20 corresponding to a periodic structure formation region 30, a perifpheral region 40, polarization inversion regions 32, and a connection region 42, to be formed or set in the substrate 10. In setting these zones, for example, a mask, used in photolithographic exposure, is employed. The zone in the insulating film 20 corresponding to the periodic structure formation region 30 is the periodic structure formation zone 50. The zone in the insulating film 20 corresponding to the peripheral region 40 is the peripheral zone 60. The zones in the insulating film 20 corresponding to the polarization inversion zones 32 are polarization inversion zones 52. Furthermore, the zone in the insulating film 20 corresponding to the connection region 42 is the connection zone 62.

Thereafter, the portions of the insulating film 20 in the polarization inversion zones 52 and connection zone 62 are removed, and openings 25 are formed which cause the first principal surface 12 to be exposed in the portions of the polarization inversion regions 32 and connection region 42 in the substrate 10. Here, resist is used as the insulating film 20, so that by means of an arbitrary appropriate and well-known photolithographic process, the portions of the insulating film 20 in prescribed regions are removed. In the following explaination, insulating film in which openings 25 are formed is called an insulating film pattern 22 (FIGS. 2C and 2D).

As the insulating film 20, a silicon oxide film (SiO₂ film), aluminum oxide film (Al₂O₃ film), silicon nitride film (SiN film), polyimide, or other organic polymer film, may for example be formed by an arbitrary appropriate and well-known chemical phase vapor desposition (CVD) method. In this case, an arbitrary and appropriate well-known photolithographic and dry etching method, life-off method or similar are used to remove the portions of the insulating film 20 in prescribed regions.

When a high voltage is applied, through an electrolytic solution, across the first principal surface 12 exposing the substrate 10 and the second principal surface 14, the direction of polarization is inverted in the polarization inversion regions 32 of the substrate 10, in which the first principal surface 12 is exposed from the opening 25 of the insulating film pattern 22. This application of high voltage will be explained referring to FIG. 3.

A structure 15, in which the insulating film pattern 22 is formed on the first principal surface 12 of the substrate 10, is fixed within a container 70. The container 70 comprises an upper (or a first) container 70a and a lower (or a second) container 70b. The upper container 70a is fixed, via an O-ring 72a of rubber or similar, to the face of the structure 15 on the side of the first principal surface 12. The space surrounded by the substrate 10 and the upper container 70a is filled with an electrolytic solution 76. The lower container 70b is fixed, via an O-ring 72b of rubber or similar, to the face of the structure 15 on the side of the second principal surface 14. The space surrounded by the substrate 10 and the lower container 70b is filled with the electrolytic solution 76. As the electrolytic solution 76, for example, an aqueous solution of LiCl, NaCl, KCl or another alkali metal salt, or an aqueous solution of MgCl₂, BaCl₂, or another alkali earth metal salt, is used.

The upper container 70a and lower container 70b respectively comprise an upper (or a first) electrode 84a and lower (or a second) electrode 84b. The upper electrode 84a and lower electrode 84b are connected to a high-voltage power supply 80 via wires 82 drawn to the outside of the upper container 70a and lower container 70b. When a voltage is applied across the upper electrode 84a and lower electrode 84b, a voltage is applied, across the exposed first principal surface 12 and the second principal surface 14 of the substrate 10, through the electrolytic solution 76. As a result, the polarization in the portions of the substrate 10 to which the voltage is applied is inverted. The voltage applied across the upper electrode 84a and lower electrode 84b may be a direct-current voltage or a pulsed voltage, and the magnitude of the voltage need only be as large as or larger than a voltage causing polarization inversion in the substrate 10. As a result of the occurrence of polarization inversion in the polarization inversion regions, the nonlinear optical element 17 explained referring to FIG. 1 is obtained.

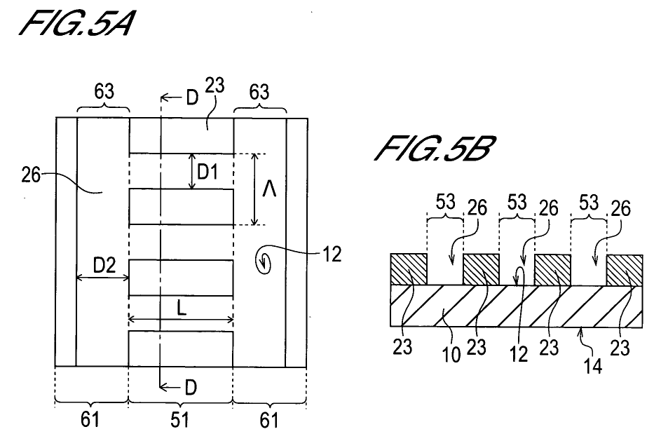

The spreading of the source inducing polarization inversion will be explained with reference to FIGS. 4A and 4B. FIG. 4A shows a case in which an insulating film pattern 24 used in a method of the prior art is used; FIG. 4B shows a case in which the insulating film pattern 22 used in the method of the first aspect is used. In FIGS. 4A and 4B, some portions are represented by dot-hatching, which are not sections thereof.

When using the insulating film pattern 24 of the method of the prior art, it is supposed that applying a high voltage to one among the plurality of polarization inversion regions 34 (in FIG. 4A, the portion indicated by the symbol 34a), polarization inversion does not occur. At this time, even if polarization inversion has occurred in the other polarization inversion regions 34 (in FIG. 4A, portions indicated by 34b and 34c), because the individual polarization inversion regions are mutually independent, the portion 34a in which polarization inversion has not occurred remains with no occurrence of polarization inversion. As a result, the distribution of regions in which polarization inversion has occurred becomes uneven.

On the other hand, when using the insulating film pattern 22 of the first embodiment, even if polarization inversion does not occur in one among the plurality of polarization inversion regions 32 (in FIG. 4B, indicated by the symbol 32a), if polarization inversion occurs in the other polarization inversion regions (in FIG. 4B, portions indicated by 32b and 32a), the source inducing polarization inversion spreads via the connection region 42 (in FIG. 4B, indicated by arrows). Consequently polarization inversion occurs even in portions in which polarization inversion does not at first occur. As a result, polarization inversion occurs over the entirety of the polarization inversion region 32a, and the overall substrate has a uniform polarization inversion periodic structure.

By means of the method of manufacture of a nonlinear optical element of the first embodiment, a plurality of periodically arranged polarization inversion regions are connected by a connection region, so that a source inducing polarization inversion occurring in one polarization inversion region or in the connection region can easily spread to other polarization inversion regions. Hence uniform polarization inversion regions can be formed through all areas of the substrate.

Moreover, when the plurality of polarization inversion regions are set in a rectangular shape with the length direction in a first direction and with the width being a first width, and the connection region is set in a rectangular shape with the length direction in a second direction perpendicular to the first direction and with width being a second width greater than the first width, the connection region is wider than the polarization inversion regions. Consequently the source inducing polarization inversion in the connection region occurs readily. Hence it is easier still to obtain a uniform distribution.

The widths of individual polarization inversion regions, and the period at which polarization inversion regions are set, may be determined so as to realize quasi-phase matching according to the wavelength of the light to be used.

Second Embodiment

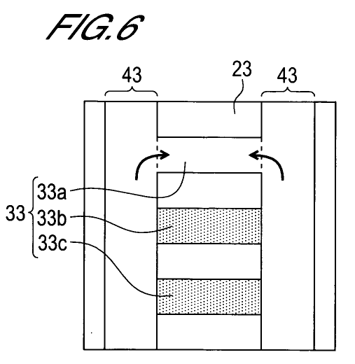

The method of manufacture of a nonlinear optical element of a second embodiment will be explained with reference to FIGS. 5A and 5B.

In the second embodiment, the shape of the insulating film pattern is different from that in the first embodiment. Other portions are similar to those in the first embodiment, and redundant explanations are omitted.

In the second embodiment, the plurality of polarization inversion zones 53 in the periodic structure formation zone 51 are set in a rectangular shape with the length direction in a first direction, and with the width equal to a first width. The peripheral zones 61 are set on both sides of the periodic structure formation zone 51 with respect to the first direction. Connection zones 63 are set in a rectangular shape within the peripheral zones 61 set on both sides of the periodic structure formation zone 51, and have length direction in a second direction perpendicular to the first direction , and width equal to a second width greater than the first width. The insulating film patter 23 of the second embodiment has openings 26 which expose the first principal surface 12 in the portions of the polarization inversion zones 53 and connection zones 63.

Spreading of the source inducing polarization inversion will be explained, referring to FIG. 6. FIG. 6 shows spreading of the source which induces polarization inversion, when using the insulating film pattern 23 used in the second embodiment.

When using the insulating film pattern 22 of the first embodiment, if polarization inversion has not occurred in a portion of the polarization inversion regions 32 (the portion indicated by the symbol 32a in FIG. 4B), but if polarization inversion occurs in other portions of the polarization inversion regions 32 (in FIG. 4B, the portions indicated by 32b and 32c), then the source inducing polarization inversion spreads via the connection region 42 (indicated by arrows in FIG. 4B).

On the other hand, when using the insulating film pattern 23 of the second embodiment, connection regions 43 are set on both sides of the length direction of the polarization inversion regions 33, so that even when polarization inversion has not occurred in a portion of the polarization inversion regions 33 (in FIG. 6, the portion indicated by the symbol 33a), if polarization inversion has occurred in the other portion of the polarization inversion regions 33 (in FIG. 66, the portions indicated by 33b and 33c), the source inducing polarization inversion spreads from both sides of the polarization inversion region 33a, via the connection regions 43.

Providing connection regions on both sides of the length direction of the polarization inversion regions, the source inducing polarization inversion spreads from both sides of the polarization inversion regions.

### EXAMPLES

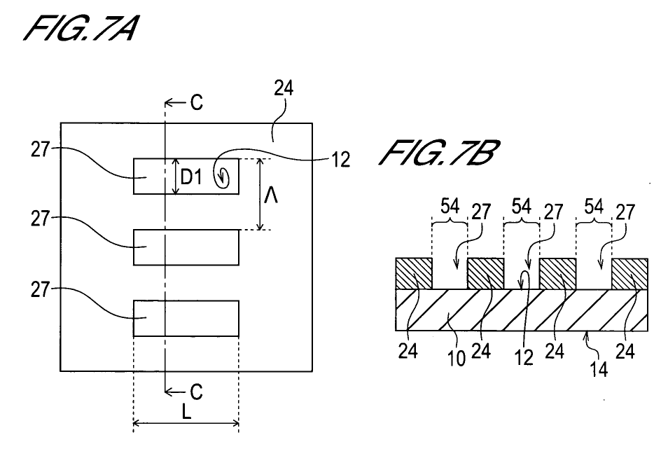

Cases are compared using the insulating film pattern of the prior art, explained referring to FIG. 7, and the insulating film pattern of the second embodiment, explained referring to FIG. 5.

As the substrate 400 μm thick LiNbO₃ substrate was used; the insulating film patterns 23 and 24 were formed using resist. As the electrolytic solution, a LiCl aqueous solution was used; when a voltage of 2.5 kV was applied across the upper electrode and lower electrode, polarization inversion occurred.

The polarization inversion zones 53 and 54 of the insulating film patterns 23 and 24 both have a period Λ of the polarization inversion regions 33 (see FIG. 6) and 34 (see FIG. 4A) of 18 μm, and the width D1 is set to be 9 μm. In the insulating film pattern 23 of the second embodiment, the connection zone 63 is set such that the width D2 of the connection region 43 (FIG. 6) is 20 μ. In FIGS. 5 and 7, the polarization inversion zones 53 and 54 set in the insulating film patterns 23 and 24, and the polarization inversion regions 33 and 34 formed in the substrate, are assumed to be of the same shaper and size; further, the connection zone 63 set in the insulating pattern 23 and the connection region 43 formed in the substrate are assumed to be of the same shape and size.

After causing polarization inversion, selective etching of the first principal surface of the substrate was performed using a mixed solution of hydrofluoric acid and nitric acid, and the surface was then observed with a microscope. As a result, when an insulating film pattern 24 of the prior art was used, in the polarization inversion regions 34 polarization inversion had occurred in approximately 80 to 85% of the regions, whereas when the insulating film pattern 23 of the second embodiment was used, it was confirmed that the fraction was substantially 100%, that is, polarization inversion had occurred according to the insulating film pattern.

As another embodiment, similar measurements were performed using as the substrate a LiNbO₃ substrate containing MgO. As a result, when an insulating film pattern 23 of the prior art was used, approximately 40% to 60% of the regions of the polarization inversion regions 34 had undergone polarization inversion, whereas when the insulating film pattern 23 of the second embodiment was used, the fraction was substantially 100%, that is polarization inversion was confirmed to have occurred according to the insulating film pattern 23.

What is claimed is:

1. A method for manufacturing a nonlinear optical element having a periodic polarization inversion structure, comprising steps of:
preparing a substrate made of a nonlinear optical material;
forming an insulating film on a first principal surface of said substrate;
setting, on the insulating film, a periodic structure formation zone corresponding to a periodic structure formation region to be formed on said substrate; a peripheral zone adjacent to said periodic structure formation zone; a plurality of polarization inversion zones corresponding to polarization inversion regions to be formed in a periodic arrangement in said periodic structure formation region; and a connection zone, within said peripheral zone, corresponding to a connection region which connects said plurality of polarization inversion regions, to be formed on said substrate,
forming an insulating film pattern which exposes portions of the first principal surface of said substrate by removing portions of said insulating film in said polarization inversion zones and said connection zone; and
applying a high voltage, through an electrolytic solution, across the portions of a first principal surface exposed out of said insulating film pattern and a second principal surface of said substrate, to cause inversion of the polarization direction of the substrate portions in the polarization inversion regions.

2. The method for manufacturing a nonlinear optical element according to Claim 1, wherein
during forming said insulating film pattern, said polarization inversion zones are set in a rectangular shape, with length direction in a first direction, and with width being a first width, and
said connection zone is set in a rectangular shaper, with length direction in a second direction perpendicular to said first direction, and with width being a second width greater than said first width.

3. The method for manufacturing a nonlinear optical element according to Claim 1, wherein
during forming said insulating film patter, said polarization inversion zones are set in a rectangular shape, with length direction in a first direction, and with width being a first width;
said peripheral zone is set separately on both sides along the direction of arrangement of said polarization inversion zones in said periodic structure formation zone; and
said connection zone is set in a rectangular shape in each of said set peripheral zones, with length direction in a second direction perpendicular to said first direction, and with width being a second width greater than said first width.

4. The method for manufacturing a nonlinear optical element according got Claim 1, wherein said substrate is formed from a ferroelectric crystal.

5. The method for manufacturing a nonlinear optical element according to Claim 1, wherein said substrate is formed from a ferroelectric crystal comprising magnesium, iron, or zinc.

6. The method for manufacturing a nonlinear optical element according to Claim 1, wherein said substrate is formed from a ferroelectric crystal comprising an oxide of magnesium, an oxide of iron, or an oxide of zinc.

7. The method for manufacturing a nonlinear optical element according to any one of Claims 4 through 6, wherein
said ferroelectric crystal is formed from any one among LiNbO₃ (LN), LiTaO₃ (LT), KTi0PO₄ (KTP), LiNbP₄O₁₂ (LNP), KNbO₃ (KN), Ba₂NaNb₅O₁₅ (BNP), KTiOAsO₄ (KTA), BaB₂O₄ (BBO), LiB₃O₇ (LBO), and KH₂PO₄ (KDP).

8. The method for manufacturing a nonlinear optical element according to Claim 1, wherein said substrate is formed from an organic nonlinear optical material.

9. The method for manufacturing a nonlinear optical element according to Claim 8, whereing
said substrate is formed from one organic nonlinear optical material from among metro-nitroaniline, 2-methyl-4-nitroaniline, 4-bromo-4-methoxychalcone, and dicyano-vinylanisole.

10. The method for manufacturing a nonlinear optical element according to Claim 1, wherein said insulating film is formed by applying a photosensitive organic polymer film.
